(19) United States
(12) Patent Application Publication
(10) Pub. No.: US 2025/0151581 A1
(43) Pub. Date: May 8, 2025

(54) ENCAPSULATION LAYER, DISPLAY APPARATUS INCLUDING THE ENCAPSULATION LAYER, AND METHOD OF MANUFACTURING THE DISPLAY APPARATUS

(71) Applicant: Samsung Display Co., Ltd., Yongin-si (KR)

(72) Inventors: Hyein Jung, Yongin-si (KR); Yeonguk Kim, Yongin-si (KR); Heeyeon Park, Yongin-si (KR); Changyeong Song, Yongin-si (KR); Yongchan Ju, Yongin-si (KR); Jaeheung Ha, Yongin-si (KR)

(21) Appl. No.: 18/742,784

(22) Filed: Jun. 13, 2024

(30) Foreign Application Priority Data
Nov. 6, 2023 (KR) 10-2023-0151939

(51) Int. Cl. H10K 59/80; H10K 59/12; H10K 102/00

(52) U.S. Cl. CPC H10K 59/873; H10K 59/1201; H10K 2102/351

(57) ABSTRACT

An encapsulation layer that is thin and is capable of blocking external moisture and/or oxygen is described. The encapsulation layer includes a first layer including polysilazane and a second layer disposed on the first layer and including a cured product of a silicon-based vinyl monomer.

### CROSS-REFERENCE TO RELATED APPLICATION

The present application claims priority to and the benefit of Korean Patent Application No. 10-2023-0151939, filed on Nov. 6, 2023, in the Korean Intellectual Property Office, the entire disclosure of which is incorporated herein by reference.

### BACKGROUND

### 1. Field

One or more embodiments relate to an encapsulation layer, a display apparatus including the encapsulation layer, and a method of manufacturing the display apparatus. For example, one or more embodiments relate to an encapsulation layer that is thin and is capable of blocking external moisture and/or oxygen, a display apparatus including the encapsulation layer, and a method of manufacturing the display apparatus.

### 2. Description of the Related Art

A display apparatus may include an organic light-emitting diode as a display element. An organic light-emitting diode includes a pixel electrode, an opposite electrode, and an intermediate layer interposed therebetween and includes an emission layer. Because such an organic light-emitting diode may be easily damaged by external moisture and/or oxygen, an encapsulation layer is utilized to cover the organic light-emitting diode so as to protect the organic light-emitting diode.

### SUMMARY

In a related art display apparatus, an encapsulation layer has to be thick enough to block or reduce external moisture and/or oxygen. However, when the encapsulation layer is too thick, it may be difficult to fold or bend the display apparatus (e.g., folding or bending may not be facilitated) and the aesthetics of the display apparatus may be reduced.

Aspects according to one or more embodiments are directed toward an encapsulation layer that is relatively thin and capable of blocking external moisture and/or oxygen, a display apparatus including the encapsulation layer, and a method of manufacturing the display apparatus. However, this is merely an example and the scope of the disclosure is not limited thereby.

Additional aspects will be set forth in part in the description which follows and, in part, will be apparent from the description, or may be learned by practice of the presented embodiments of the disclosure.

According to one or more embodiments, an encapsulation layer includes a first layer including polysilazane, and a second layer on the first layer and including a cured product of a silicon-based vinyl monomer.

The polysilazane may include perhydropolysilazane (PHPS).

The silicon-based vinyl monomer may include at least one of vinyltrimethylsilane, vinyltriethylsilane, vinyltrimethoxysilane, vinyltriethoxysilane, vinyltris(2-methoxyethoxy)silane, vinyltrisisopropoxysilane, vinyltris(tertbutylperoxy)silane, vinyldimethylethoxysilane, vinylmethyldimethoxysilane, vinylmethyldiethoxysilane, 1,1,3,3-tetramethyl-1,3-divinyldisiloxane, 2,4,6,8-tetramethyl-2,4,6,8-tetravinyl-cyclotetrasiloxane, or 1,3,5-trivinyl-1,3,5-trimethylcyclotrisiloxane.

A portion of the polysilazane of the first layer may form a covalent bond with the silicon-based vinyl monomer.

The second layer may be in direct contact with the first layer.

A thickness of the encapsulation layer may be about 0.3 μm to about 1.0 μm.

The encapsulation layer may further include a third layer on the second layer and including polysilazane.

According to one or more embodiments, a display apparatus includes a substrate, a display element on the substrate, and an encapsulation layer covering the display element, the encapsulation layer including a first layer including polysilazane and a second layer on the first layer and including a cured product of a silicon-based vinyl monomer.

The polysilazane may include perhydropolysilazane (PHPS).

The silicon-based vinyl monomer may include at least one of vinyltrimethylsilane, vinyltriethylsilane, vinyltrimethoxysilane, vinyltriethoxysilane, vinyltris(2-methoxyethoxy)silane, vinyltrisisopropoxysilane, vinyltris(tertbutylperoxy)silane, vinyldimethylethoxysilane, vinylmethyldimethoxysilane, vinylmethyldiethoxysilane, 1,1,3,3-tetramethyl-1,3-divinyldisiloxane, 2,4,6,8-tetramethyl-2,4,6,8-tetravinyl-cyclotetrasiloxane, or 1,3,5-trivinyl-1,3,5-trimethylcyclotrisiloxane.

A portion of the polysilazane of the first layer may form a covalent bond with the silicon-based vinyl monomer.

The second layer may be in direct contact with the first layer.

A thickness of the encapsulation layer may be about 0.3 μm to about 1.0 μm.

The encapsulation layer may further include a third layer on the second layer, the third layer including at least one of polysilazane, silicon nitride, silicon oxide, or silicon oxynitride.

According to one or more embodiments, a method of manufacturing a display apparatus includes forming a display element on a substrate; forming a first preliminary layer by applying a material including polysilazane to cover the display element; forming a first layer by emitting ultraviolet light to the first preliminary layer; forming a second preliminary layer by applying a material including a silicon-based vinyl monomer on the first layer; and forming a second layer by emitting ultraviolet light to the second preliminary layer.

The polysilazane may include perhydropolysilazane (PHPS).

The silicon-based vinyl monomer may include at least one of vinyltrimethylsilane, vinyltriethylsilane, vinyltrimethoxysilane, vinyltriethoxysilane, vinyltris(2-methoxyethoxy)silane, vinyltrisisopropoxysilane, vinyltris(tertbutylperoxy)silane, vinyldimethylethoxysilane, vinylmethyldimethoxysilane, vinylmethyldiethoxysilane, 1,1,3,3-tetramethyl-1,3-divinyldisiloxane, 2,4,6,8-tetramethyl-2,4,6,8-tetravinyl-cyclotetrasiloxane, or 1,3,5-trivinyl-1,3,5-trimethylcyclotrisiloxane.

In the forming of the second layer, a portion of the polysilazane of the first layer may form a covalent bond with the silicon-based vinyl monomer.

A sum of a thickness of the first layer and a thickness of the second layer may be about 0.3 μm to about 1.0 μm.

The method may further include forming a third preliminary layer by applying a material including polysilazane to cover the second layer; and forming a third layer by emitting ultraviolet light to the third preliminary layer.

Other aspects, features, and enhancements of the disclosure will become better understood through the detailed description, the claims, and the accompanying drawings.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and enhancements of certain embodiments of the disclosure will be more apparent from the following description taken in conjunction with the accompanying drawings, in which:

FIG. 1 is a plan view schematically illustrating a display apparatus according to an embodiment;

FIG. 2 is an equivalent circuit diagram of a pixel circuit included in a display apparatus, according to an embodiment;

FIG. 3 is a cross-sectional view schematically illustrating the display apparatus of FIG. 1 taken along the line I-I′ of FIG. 1;

FIG. 4 is a cross-sectional view schematically illustrating a display apparatus according to another embodiment;

FIG. 5 is a cross-sectional view schematically illustrating a display apparatus according to a comparative example;

FIGS. 6-10 are cross-sectional views schematically illustrating a process of manufacturing a portion of the display apparatus of FIG. 3; and

FIGS. 11 and 12 are cross-sectional views schematically illustrating a process of manufacturing a portion of the display apparatus of FIG. 4.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described by referring to the drawings to explain aspects of the present description. As used herein, the term “and/or” includes any and all combinations of one or more of the associated listed items. Throughout the disclosure, the expression “at least one of a, b or c” or “at least one of a, b and c” indicates only a, only b, only c, both (e.g., simultaneously) a and b, both (e.g., simultaneously) a and c, both (e.g., simultaneously) b and c, all of a, b, and c, or variations thereof.

As the present description allows for one or more suitable changes and numerous embodiments, certain embodiments will be illustrated in the drawings and described in more detail in the written description. Effects and features of the disclosure, and methods of achieving them will be clarified with reference to one or more embodiments described below in more detail with reference to the drawings. However, the disclosure is not limited to the following embodiments and may be embodied in one or more suitable forms.

In this specification, it will be understood that although the terms “first,” “second,” and/or the like may be used herein to describe one or more suitable elements, these elements should not be limited by these terms. These terms are only used to distinguish one element from another.

The singular forms as used herein are intended to include the plural forms as well unless the context clearly indicates otherwise.

In the present specification, it will be understood that the terms “include” and/or “comprise” as used herein specify the presence of stated features or elements, but do not preclude the presence or addition of one or more other features or elements.

In this specification, the expression “A and/or B” indicates only A, only B, or both (e.g., simultaneously) A and B. In this specification, the expression “at least one of A and B” or “at least one of A or B” indicates only A, only B, or both (e.g., simultaneously) A and B.

In the present specification, it will be understood that, when an element such as a layer, film, region, or plate is referred to as being “on” another element, this may be “directly on” the other element, but also intervening elements may be present therebetween.

It will be further understood that when layers, regions, or elements are

referred to as being connected to each other, they may be directly connected to each other or indirectly connected to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

In the present specification, the x-axis, the y-axis, and the z-axis are not limited to three axes of the rectangular coordinate system and may be interpreted in a broader sense. For example, the x-axis, the y-axis, and the z-axis may be normal (e.g., perpendicular) to one another or may represent different directions that are not normal (e.g., perpendicular) to one another.

When a certain embodiment may be implemented differently, a specific process order may be performed differently from the described order. For example, two consecutively described processes may be performed substantially at the same time or performed in an order opposite to the stated order.

The term “in a plan view” as used herein refers to seeing a target portion from above. For example, in the present specification, the term “in a plan view” as used herein may refer to “when viewed from a direction normal (e.g., perpendicular) to a substrate.”

Hereinafter, embodiments will be described in more detail with reference to the accompanying drawings. When describing embodiments with reference to the accompanying drawings, the same or corresponding elements are denoted by the same reference numerals, and redundant descriptions thereof will not be provided. For convenience of explanation, sizes of elements in the drawings may be exaggerated or reduced. For example, because sizes and thicknesses of elements in the drawings are arbitrarily illustrated for convenience of explanation, the disclosure is not limited thereto.

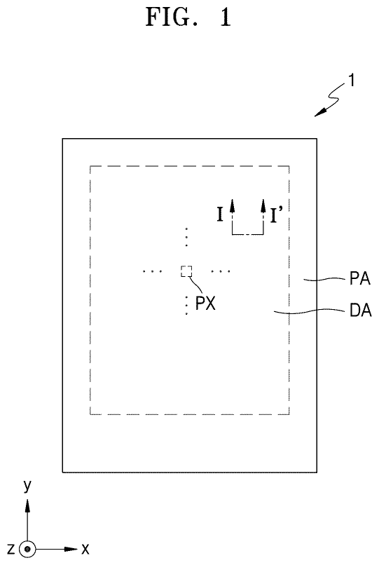

FIG. 1 is a plan view schematically illustrating a display apparatus 1 according to an embodiment.

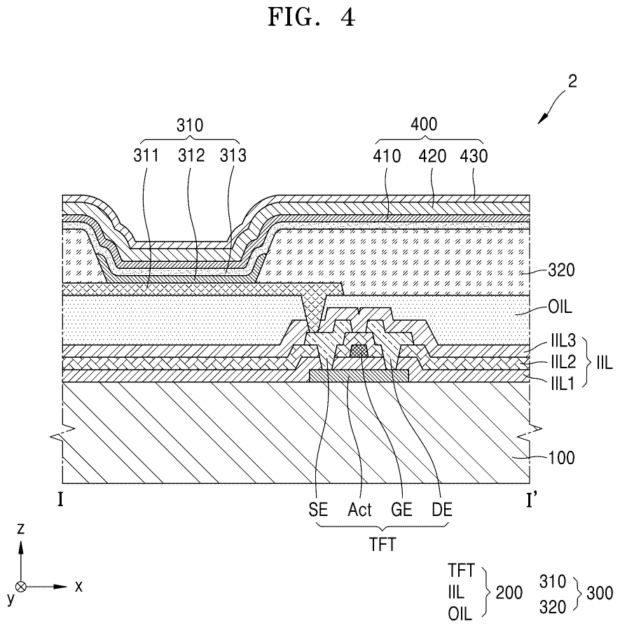

As illustrated in FIG. 1, the display apparatus 1 may include a display area DA in which a plurality of pixels PX are arranged and a peripheral area PA outside the display area DA. For example, the peripheral area PA may completely surround the display area DA. It may be understood that a substrate (see 100 of FIG. 4) included in the display apparatus 1 has the display area DA and the peripheral area PA.

The pixels PX of the display apparatus 1 are areas in which light (e.g., pieces of light) of certain colors are emitted, and the display apparatus 1 may provide images by utilizing the light (e.g., pieces of light) emitted from the pixels PX. The pixels PX may emit, for example, red light, green light, or blue light, externally (e.g., to the outside).

The display area DA may have a polygonal shape including a rectangular shape, as illustrated in FIG. 1. For example, the display area DA may have a rectangular shape with a horizontal length longer than a vertical length, a rectangular shape with a horizontal length shorter than a vertical length, or a square shape. In one or more embodiments, the display area DA may have various suitable shapes, for example, an elliptical shape or a circular shape.

The peripheral area PA may be a non-display area in which the pixels PX are not arranged. A driver and/or the like configured to provide electrical signals or power to the pixels PX may be arranged in the peripheral area PA. Pads, to which one or more suitable electronic devices or a printed circuit board may be electrically connected, may be arranged in the peripheral area PA. The pads may be apart from 1 each other in the peripheral area PA and may be electrically connected to a printed circuit board or integrated circuit devices.

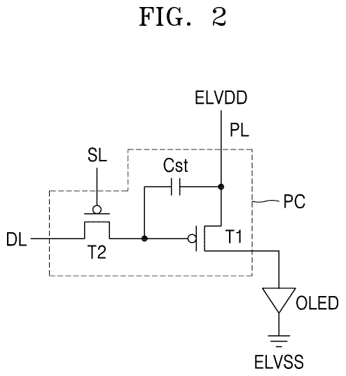

FIG. 2 is an equivalent circuit diagram of a pixel circuit PC included in the display apparatus 1 of FIG. 1, according to an embodiment. The pixel circuit PC may be electrically connected to a display element. One display element may correspond to one pixel PX. In FIG. 2, an organic light-emitting diode OLED is illustrated as the display element.

The pixel circuit PC may include a first transistor T1, a second transistor T2, and a storage capacitor Cst. The second transistor T2, which acts as a switching transistor, may be connected to a scan line SL and a data line DL and may be configured to be turned on in response to a switching signal input from the scan line SL and transmit, to the first transistor T1, a data signal input from the data line DL. The storage capacitor Cst may have one end electrically connected to the second transistor T2 and the other end electrically connected to a driving voltage line PL and may store a voltage corresponding to a difference between a voltage received from the second transistor T2 and a driving power supply voltage ELVDD supplied to the driving voltage line PL.

The first transistor T1, which acts as a driving thin-film transistor, may be connected to the driving voltage line PL and the storage capacitor Cst and may be configured to control an amount of a driving current flowing from the driving voltage line PL to the organic light-emitting diode OLED according to a voltage value stored in the storage capacitor Cst. The organic light-emitting diode OLED may be configured to emit light having a certain luminance according to the driving current. An opposite electrode of the organic light-emitting diode OLED may be configured to receive an electrode power supply voltage ELVSS.

Although FIG. 2 illustrates that the pixel circuit PC includes two thin-film transistors and one storage capacitor, the disclosure is not limited thereto. For example, the number of transistors or the number of storage capacitors may be variously suitably changed according to the design of the pixel circuit PC.

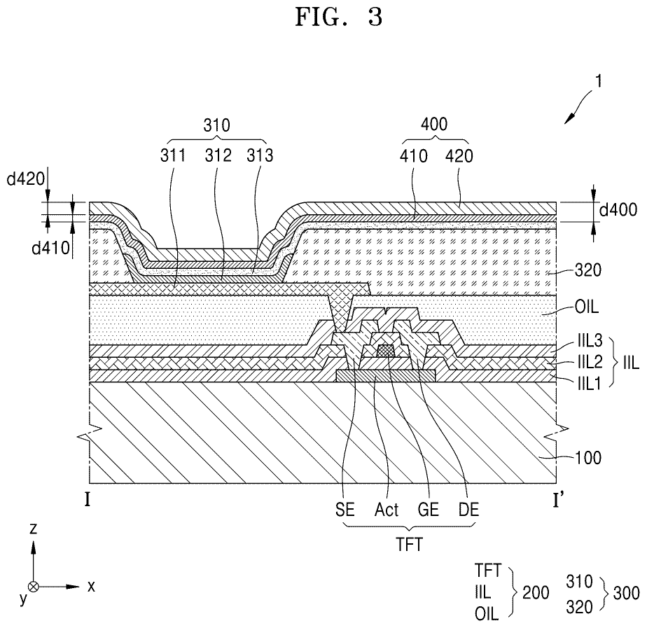

FIG. 3 is a cross-sectional view schematically illustrating the display apparatus 1 of FIG. 1 taken along the line I-I′ of FIG. 1. As illustrated in FIG. 3, the display apparatus 1 may include a substrate 100, a pixel circuit layer 200, a display element layer 300, and an encapsulation layer 400.

The substrate 100 may include glass, metals, or polymer resin. In some embodiments, the substrate 100 may be flexible and/or bendable. In this case, the substrate 100 may include, for example, a polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. Various suitable modifications are possible. In some embodiments, the substrate 100 may have a multilayer structure including two layers, each including a polymer resin, and a barrier layer including an inorganic material (e.g., silicon oxide (SiOₓ), silicon nitride (SiNₓ), silicon oxynitride (SiOₓN_{y}), and/or the like) between the two layers.

The pixel circuit layer 200 may be arranged on the substrate 100. The pixel circuit layer 200 may include a thin-film transistor TFT, an inorganic insulating layer IIL, and an organic insulating layer OIL. The thin-film transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, one thin-film transistor TFT is illustrated in FIG. 3, and the thin-film transistor TFT may correspond to the first transistor T1 of FIG. 2 described above.

The semiconductor layer Act may be arranged on the substrate 100. The semiconductor layer Act may include polysilicon. In one or more embodiments, the semiconductor layer Act may include amorphous silicon, an oxide semiconductor, or an organic semiconductor. In an embodiment, the semiconductor layer Act may include a channel region, and a source region and a drain region respectively on both sides (e.g., opposite sides) of the channel region.

The gate insulating layer IIL1 may be arranged on the semiconductor layer Act and the substrate 100. The gate insulating layer IIL1 may include an inorganic insulating material, such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnOₓ). The zinc oxide (ZnOₓ) may include ZnO and/or ZnO₂.

The gate electrode GE may be arranged on the gate insulating layer IIL1. For example, because the gate insulating layer IIL1 is between the semiconductor layer Act and the gate electrode GE, insulation between the semiconductor layer Act and the gate electrode GE may be ensured. The gate electrode GE may overlap the channel region of the semiconductor layer Act. The gate electrode GE may include a low-resistance metal material. In an embodiment, the gate electrode GE may include a conductive material including molybdenum (Mo), aluminum (AI), copper (Cu), titanium (Ti), and/or the like, and may have a single-layer or multilayer structure including the conductive material described above.

The first interlayer insulating layer IIL2 may be arranged on the gate electrode GE and the gate insulating layer IIL1. The first interlayer insulating layer IIL2 may include an inorganic insulating material, such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnOₓ).

The source electrode SE and the drain electrode DE may be arranged on the first interlayer insulating layer IIL2. Each of the source electrode SE and the drain electrode DE may be connected to the semiconductor layer Act through contact holes formed in the gate insulating layer IIL1 and the first interlayer insulating layer IIL2. At least one of the source electrode SE or the drain electrode DE may include a conductive material (e.g., a conductor) including molybdenum (Mo), aluminum (AI), copper (Cu), titanium (Ti), and/or the like, and may have a single-layer or multilayer structure including the conductive material described above. In an embodiment, at least one of the source electrode SE or the drain electrode DE may have a multilayer structure of Ti/Al/Ti.

The second interlayer insulating layer IIL3 may be arranged on the source electrode SE, the drain electrode DE, and the first interlayer insulating layer IIL2. The second interlayer insulating layer IIL3 may include an inorganic insulating material, such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnOₓ).

The organic insulating layer OIL may be arranged on the second interlayer insulating layer IIL3. The organic insulating layer OIL may serve to substantially planarize the upper portion of the pixel circuit layer 200. The organic insulating layer OIL may include, for example, an organic material, such as acryl, benzocyclobutene (BCB), and/or hexamethyldisiloxane (HMDSO). Although FIG. 3 illustrates the organic insulating layer OIL as a single layer, the disclosure is not limited thereto and various suitable modifications are possible. For example, the organic insulating layer OIL may have a multilayer structure.

The display element layer 300 may be arranged on the pixel circuit layer 200. The display element layer 300 may include a display element 310 and a pixel defining layer 320. The display element 310 may be electrically connected to the thin-film transistor TFT. The display element 310 may be, for example, an organic light-emitting diode having a pixel electrode 311, an opposite electrode 313, and an intermediate layer 312 therebetween and including an emission layer. The expression “the display element 310 is electrically connected to the thin-film transistor TFT” may refer to that the pixel electrode 311 of the organic light-emitting diode is electrically connected to the thin-film transistor TFT.

The pixel electrode 311 may be electrically connected to the thin-film transistor TFT and in contact with one of the source electrode SE or the drain electrode DE through contact holes formed in the second interlayer insulating layer IIL3 and the organic insulating layer OIL. The pixel electrode 311 may include a conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the pixel electrode 311 may include a reflective layer including silver (Ag), magnesium (Mg), aluminum (AI), platinum (Pt), palladium (Pd), gold (Au), nickel (Ni), neodymium (Nd), iridium (Ir), chromium (Cr), or a (e.g., any) compound thereof. In another embodiment, the pixel electrode 311 may further include a layer including ITO, IZO, ZnO, or In₂O₃ above and/or below the reflective layer.

The pixel defining layer 320 may cover the edge of the pixel electrode 311. The pixel defining layer 320 may include a pixel opening. The pixel opening may overlap the pixel electrode 311. The pixel opening may define an emission area of light emitted from the display element 310. The pixel defining layer 320 may include an organic insulating material and/or an inorganic insulating material. In some embodiments, the pixel defining layer 320 may include a light blocking material.

The intermediate layer 312 may be arranged on the pixel electrode 311 and the pixel defining layer 320. The intermediate layer 312 may include a relatively low molecular weight material or a relatively high molecular weight material. When the intermediate layer 312 includes a relatively low molecular weight material, the intermediate layer 312 may have a single-layer or a composite stack structure including a hole injection layer (HIL), a hole transport layer (HTL), an emission layer (EML), an electron transport layer (ETL), and an electron injection layer (EIL). The intermediate layer 312 may be formed by vacuum deposition. When the intermediate layer 312 includes a relatively high molecular weight material, the intermediate layer 312 may have a structure including an HTL and an EML. In this case, the HTL may include poly(3,4-ethylene dioxythiophene (PEDOT), and the EML may include a polymer material, such as poly-phenylenevinylene (PPV) and/or polyfluorene. The intermediate layer 312 may be formed by screen printing, inkjet printing, laser induced thermal imaging (LITI), and/or the like. The intermediate layer 312 is not necessarily limited thereto and may have various suitable structures. The intermediate layer 312 may include an integral layer over a plurality of pixel electrodes 311, or may include a layer patterned to correspond to the pixel electrodes 311.

The opposite electrode 313 may be arranged on the intermediate layer 312 and the pixel defining layer 320. The opposite electrode 313 may be integrally formed as a single body in the organic light-emitting diodes and may correspond to the pixel electrodes 311. The opposite electrode 313 may include a transmissive conductive layer including ITO, In₂O₃, or IZO, and may also include a semi-transmissive layer including metal, such as Al and/or Ag. For example, the opposite electrode 313 may be a semi-transmissive layer including Mg and/or Ag.

Because the display elements 310 may be easily damaged by external moisture and/or oxygen, the encapsulation layer 400 may cover the display elements 310 so as to protect the display elements 310. The encapsulation layer 400 may include a first layer 410 and a second layer 420, as illustrated in FIG. 3.

The first layer 410 may be arranged on the opposite electrode 313. For example, the first layer 410 may cover the opposite electrode 313. For example, the first layer 410 may cover the display element 310. The first layer 410 may include polysilazane. The polysilazane may be perhydropolysilazane (PHPS). In some embodiments, the first layer 410 may be a layer formed by curing (e.g., cross-linking) polysilazane. For example, the first layer 410 may include high molecular weight polysilazane formed by curing low molecular weight polysilazane. For example, polysilazane that is not photocured may have a structure represented by Formula 1. However, the disclosure is not limited thereto.

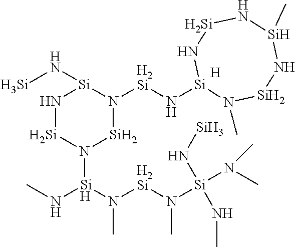

The second layer 420 may be arranged on the first layer 410. For example, the second layer 420 may cover the first layer 410. The second layer 420 may be in direct contact with the first layer 410. For example, the second layer 420 may be in surface contact with the first layer 410. The second layer 420 may include a cured (e.g., cross-linked) product of silicon-based vinyl monomer. For example, the second layer 420 may be a layer formed by curing a silicon-based vinyl monomer. In this specification, the silicon-based vinyl monomer refers to a monomer that includes a silicon-containing functional group and a vinyl group. The silicon-containing functional group may be a silane group or a siloxane group.

For example, the silicon-based vinyl monomer may include at least one of vinyltrimethylsilane, vinyltriethylsilane, vinyltrimethoxysilane, vinyltriethoxysilane, vinyltris(2-methoxyethoxy)silane, vinyltrisisopropoxysilane, vinyltris(tertbutylperoxy)silane, vinyldimethylethoxysilane, vinylmethyldimethoxysilane, vinylmethyldiethoxysilane, 1,1,3,3-tetramethyl-1,3-divinyldisiloxane, 2,4,6,8-tetramethyl-2,4,6,8-tetravinyl-cyclotetrasiloxane, or 1,3,5-trivinyl-1,3,5-trimethylcyclotrisiloxane. In some embodiments, the silicon-based vinyl monomer may be vinyltrimethylsilane. For example, vinyltrimethylsilane may have a structure represented by Formula 2. However, the disclosure is not limited thereto.

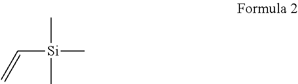

In some embodiments, a solution formed by dissolving polysilazane in a solvent is discharged onto the display element 310 by utilizing inkjet printing and a first preliminary layer is formed by removing the solvent. Then, the first layer 410 is formed by photocuring the first preliminary layer. A solution formed by dissolving a silicon-based vinyl monomer in a solvent is applied onto the first layer 410 by utilizing inkjet printing and a second preliminary layer is formed by removing the solvent. Then, the second layer 420 is formed by photocuring the second preliminary layer. Fine cracks present on the surface of the first layer 410 may be removed (e.g., filled) by the silicon-based vinyl monomer utilized to form (or provide) the second layer 420.

For example, due to a process such as solvent removal and/or photocuring when forming (or providing) the first layer 410, fine cracks may be present on the surface of the first layer 410. Such cracks may become a path through which external moisture and/or oxygen penetrates into the interior of the display apparatus 1. However, a portion of the silicon-based vinyl monomer utilized to form (or provide) the second layer 420 may undergo a reaction with the polysilazane of the first layer 410 during the formation of the second layer 420 as shown in Reaction Scheme 1. Reaction Scheme 1 shows only a portion of the polysilazane that reacts with the silicon-based vinyl monomer. For example, a portion of the polysilazane of the first layer 410 may form a covalent bond with (e.g., a portion of) the silicon-based vinyl monomer. Silicon (Si) of a portion of the polysilazane of the first layer 410 and carbon (C) of the silicon-based vinyl monomer may form a covalent bond. For example, the polysilazane of the first layer 410 may form a Si—C bond with the silicon-based vinyl monomer. Accordingly, the film quality of the first layer 410 may become denser. For example, the density of the first layer 410 may further increase. Accordingly, fine cracks present on the surface of the first layer 410 may be removed.

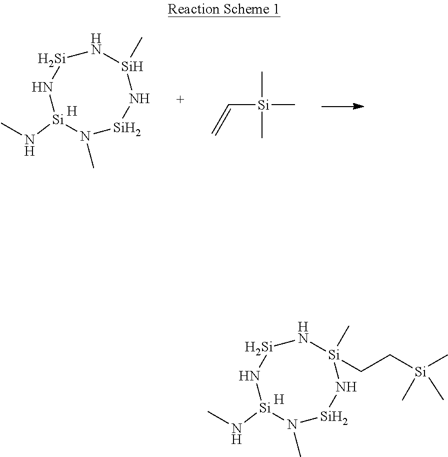

Accordingly, the encapsulation layer 400 may be thin. In some embodiments, the thickness d400 of the encapsulation layer 400 may be about 0.3 micrometer (μm) to about 1.0 μm. The thickness d400 of the encapsulation layer 400 may be the sum of the thickness d410 of the first layer 410 and the thickness d420 of the second layer 420. For example, the thickness d410 of the first layer 410 may be about 0.1 μm to about 0.4 μm, the thickness d420 of the second layer 420 may be about 0.2 μm to about 0.6 μm, and the thickness d400 of the encapsulation layer 400 may be about 0.3 μm to about 1.0 μm. In some embodiments, the thickness d410 of the first layer 410 may be about 0.1 μm to about 0.3 μm, the thickness d420 of the second layer 420 may be about 0.2 μm to about 0.4 μm, and the thickness d400 of the encapsulation layer 400 may be about 0.3 μm to about 0.7 μm. For example, the thickness d410 of the first layer 410 may be about 0.15 μm, the thickness d420 of the second layer 420 may be about 0.22 μm, and the thickness d400 of the encapsulation layer 400 may be about 0.37 μm.

In some embodiments, when the thickness d400 of the encapsulation layer 400 is less than the above value (e.g., less than about 0.3 μm), the thickness d400 of the encapsulation layer 400 may not be sufficient to block or reduce external moisture and/or oxygen. In some embodiments, when the thickness d400 of the encapsulation layer 400 is greater than the above value (e.g., greater than about 1.0 μm), the flexibility of the encapsulation layer 400 may decrease, making it difficult to fold or bend the display apparatus 1. In addition, when the thickness d400 of the encapsulation layer 400 is greater than the above value (e.g., greater than about 1.0 μm), the thickness of the display apparatus 1 may increase, and thus, the aesthetics of the display apparatus 1 may be reduced.

Although FIG. 3 illustrates that the encapsulation layer 400 includes only the first layer 410 and the second layer 420, the disclosure is not limited thereto. For example, the encapsulation layer 400 may further include a third layer 430.

FIG. 4 is a cross-sectional view schematically illustrating a display apparatus 2 according to another embodiment. Because the display apparatus 2 according to the present embodiment is similar to the display apparatus 1 described above with reference to FIGS. 1-3, differences from the display apparatus 1 described above with reference to FIGS. 1-3 are mainly described.

As illustrated in FIG. 4, an encapsulation layer 400 may include a first layer 410, a second layer 420, and a third layer 430. The encapsulation layer 400 included in the display apparatus 1 described above with reference to FIG. 3 and/or the like may include the first layer 410 and the second layer 420. The encapsulation layer 400 included in the display apparatus 2 according to the present embodiment also includes the first layer 410 and the second layer 420. However, in the display apparatus 2 according to the present embodiment, the encapsulation layer 400 may further include the third layer 430. The third layer 430 may be arranged on the second layer 420. For example, the third layer 430 may cover the second layer 420. The third layer 430 may contact (e.g., come into contact with) the first layer 410 at the edge thereof located outside the display area DA, so that the second layer 420 is not exposed to the outside.

The encapsulation layer 400 included in the display apparatus 2 according to the present embodiment may also be thin. In some embodiments, the thickness of the first layer 410 may be about 0.1 μm to about 0.4 μm, the thickness of the second layer 420 may be about 0.2 μm to about 0.6 μm, and the thickness of the third layer 430 may be about 0.1 μm to about 0.4 μm. In some embodiments, the thickness of the first layer 410 may be about 0.1 μm to about 0.3 μm, the thickness of the second layer 420 may be about 0.2 μm to about 0.4 μm, and the thickness of the third layer 430 may be about 0.1 μm to about 0.3 μm. For example, the thickness of the first layer 410 may be about 0.15 μm, the thickness of the second layer may be about 0.22 μm, and the thickness of the third layer 430 may be about 0.16 μm. Accordingly, because the encapsulation layer 400 of the display apparatus 2 is also flexible, folding or bending of the display apparatus 2 may be facilitated.

In an embodiment, the third layer 430 may include polysilazane. The polysilazane may be perhydropolysilazane (PHPS). However, the disclosure is not limited thereto. In another embodiment, the third layer 430 may include at least one of silicon oxide (SiOₓ), silicon nitride (SiNₓ), or silicon oxynitride (SiOₓN_{y}). Because the encapsulation layer 400 of the display apparatus 2 according to the present embodiment further includes the third layer 430, external moisture and/or oxygen may be blocked more effectively.

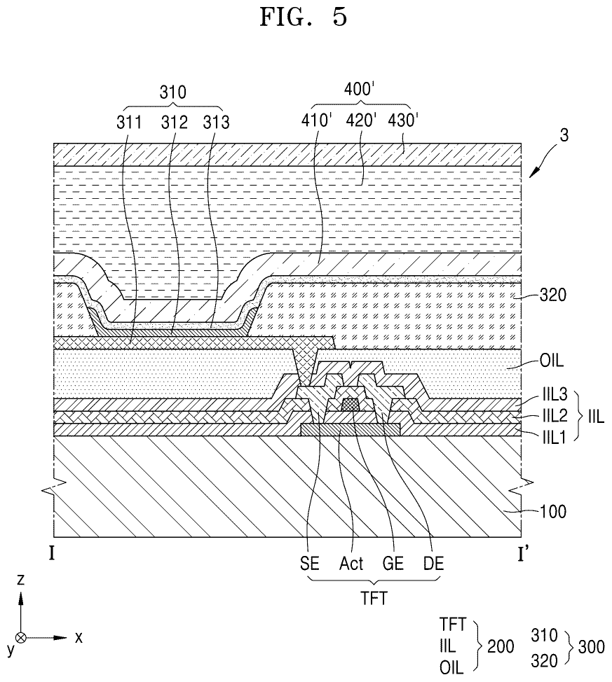

FIG. 5 is a cross-sectional view schematically illustrating a display apparatus 3 according to a comparative example. Because the display apparatus 3 according to the comparative example is similar to the display apparatus 1 according to the embodiment, differences from the display apparatus 1 according to the embodiment are mainly described.

As illustrated in FIG. 5, the display apparatus 3 according to the comparative example may include a substrate 100, a pixel circuit layer 200, and a display element layer 300. However, an encapsulation layer 400′ included in the display apparatus 3 may include a first layer 410′, a second layer 420′, and a third layer 430′. The first layer 410′ may cover an opposite electrode 313 and may include silicon oxide (SiOₓ), silicon nitride (SiNₓ), and/or silicon oxynitride (SiOₓN_{y}). The second layer 420′ may be arranged on the first layer 410′ and may include at least one material selected from among polyethylene terephthalate, polyethylene naphthalate, polycarbonate, polyimide, polyethylene sulfonate, polyoxymethylene, polyarylate, and hexamethyldisiloxane. The third layer 430′ may be arranged on the second layer 420′ and may include silicon oxide (SiOₓ), silicon nitride (SiNₓ), and/or silicon oxynitride (SiOₓN_{y}). Even when cracks occur in the first layer 410′ and the third layer 430′, the second layer 420′ may prevent or reduce the cracks occurring in the first layer 410′ from connecting to the cracks occurring in the third layer 430′. For example, the second layer 420′ may prevent or reduce such cracks from connecting to each other between the first layer 410′ and the second layer 420′ or between the second layer 420′ and the third layer 430′.

The thickness of the encapsulation layer 400′ included in the display apparatus 3 may be about 10 μm. The thickness of the encapsulation layer 400′ may be the sum of the thickness of the first layer 410′, the thickness of the second layer 420′, and the thickness of the third layer 430′. For example, the thickness of the first layer 410′ may be about 1.3 μm, the thickness of the second layer 420′ may be about 8 μm, and the thickness of the third layer 430′ may be about 0.7 μm. When the thickness of the first layer 410′, the thickness of the second layer 420′, and the thickness of the third layer 430′ are less than the respective values, the encapsulation layer 400′ may not be sufficiently thick to block or reduce external moisture and/or oxygen.

Table 1 shows the thicknesses and water vapor transmission rates (WVTRs) of the encapsulation layers of the comparative examples and the examples. The unit of the thickness is μm and the unit of the WVTR is g/m²·day. Comparative Example 1 includes an encapsulation layer including a first layer 410′, a second layer 420′, and a third layer 430′, as illustrated in FIG. 5, and Comparative Example 2 includes an encapsulation layer that does not include a second layer 420 and a third layer 430. That is, Comparative Example 2 includes an encapsulation layer including only the first layer 410, excluding the second layer 420 and the third layer 430 in the encapsulation layer 400 illustrated in FIG. 4. Example 1 includes an encapsulation layer including a first layer 410 and a second layer 420, as illustrated in FIG. 3, and Example 2 includes an encapsulation layer including a first layer 410, a second layer 420, and a third layer 430, as illustrated in FIG. 4.

TABLE 1

| | Comparative | Comparative | | |
|---|---|---|---|---|
| | Example 1 | Example 2 | Example 1 | Example 2 |
| Thickness of encapsulation | 10 | 0.1541 | 0.3756 | 0.5329 |
| layer (μm) | | | | |
| WVTR (g/m² · day) | <10⁻⁴ | >1.3 × 10⁻¹ | <10⁻⁴ | <10⁻⁴ |

Referring to Table 1, the thickness of the encapsulation layer of Comparative Example 1 is 10 μm. Specifically, the thickness of the first layer 410′ of Comparative Example 1 is 1.3 μm, the thickness of the second layer 420′ of Comparative Example 1 is 8 μm, and the thickness of the third layer 430′ of Comparative Example 1 is 0.7 μm. The encapsulation layer of Comparative Example 1 has a WVTR of less than 10⁻⁴ g/m²·day. That is, the encapsulation layer of Comparative Example 1 is able to block or reduce external moisture and/or oxygen, but is relatively thick.

The thickness of the encapsulation layer of Comparative Example 2 is 0.1541 μm. Specifically, the thickness of the first layer 410 of Comparative Example 2 is 0.1541 μm. The encapsulation layer of Comparative Example 2 has a WVTR of greater than 1.3×10⁻¹ g/m²·day. That is, the encapsulation layer of Comparative Example 2 is relatively thin, but does not sufficiently block or reduce external moisture and/or oxygen.

The thickness of the encapsulation layer of Example 2 is 0.5329 μm. Specifically, the thickness of the first layer 410 of Example 2 is 0.1541 μm, the thickness of the second layer 420 of Example 2 is 0.2215 μm, and the thickness of the third layer 430 of Example 2 is 0.1573 μm. The encapsulation layer of Example 2 is thinner than the encapsulation layer of Comparative Example 1. The encapsulation layer of Example 2 has a WVTR of less than 10⁻⁴ g/m²·day. That is, the encapsulation layer of Example 2 is thinner than the encapsulation layer of Comparative Example 1, but is able to sufficiently block or reduce external moisture and/or oxygen. Accordingly, when the encapsulation layer 400 includes the first layer 410, the second layer 420, and the third layer 430, the encapsulation layer 400 sufficiently blocks external moisture and oxygen, but is also flexible. Accordingly, folding or bending of the display apparatus 2 may be facilitated (e.g., enabled).

The thickness of the encapsulation layer of Example 1 is 0.3756 μm. Specifically, the thickness of the first layer 410 of Example 1 is 0.1541 μm and the thickness of the second layer 420 of Example 1 is 0.2215 μm. Compared to the encapsulation layer of Example 2, the encapsulation layer of Example 1 does not include the third layer 430, and thus, the encapsulation layer of Example 1 is thinner than the encapsulation layer of Comparative Example 1 and that of Example 2. The encapsulation layer of Example 1 has a WVTR of less than 10⁻⁴ g/m²·day. That is, the encapsulation layer of Example 1 is much thinner than the encapsulation layer of Comparative Example 1, but is able to sufficiently block or reduce external moisture and/or oxygen. Accordingly, even when the encapsulation layer 400 includes only the first layer 410 and the second layer 420, the encapsulation layer 400 sufficiently blocks external moisture and oxygen, but is also flexible. Accordingly, folding or bending of the display apparatus 1 may be facilitated (e.g., enabled).

The display apparatus has been described above, but the disclosure is not limited thereto. It will be stated that a method of manufacturing a display apparatus also falls within the scope of the disclosure. Hereinafter, a method of manufacturing a display apparatus will be described.

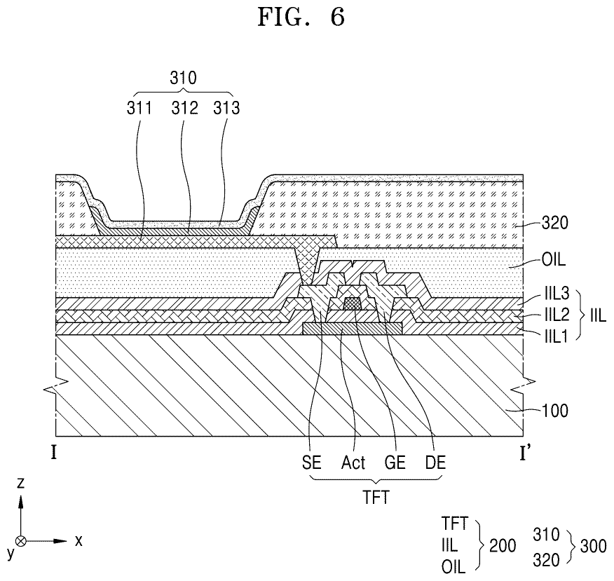

FIGS. 6-10 are cross-sectional views schematically illustrating a process of manufacturing a portion of the display apparatus 1 of FIG. 3. For example, FIGS. 6-10 are cross-sectional views schematically illustrating a process of manufacturing the encapsulation layer 400 of the display apparatus 1 of FIG. 3. In FIGS. 6-10, for convenience of explanation, the process of manufacturing the encapsulation layer 400 is described based on a cross-section of the display apparatus 1 of FIG. 3 taken along the line I-I′ of FIG. 1. Hereinafter, in describing the process of manufacturing the encapsulation layer 400 with reference to FIGS. 6-10, the same reference numerals as those in FIGS. 1-3 denote the same members, and thus, redundant descriptions thereof are omitted (not repeated). Here, the listing of the process in a particular order should not necessarily means that the invention or claims require that particular order. That is, the general rule that unless the steps, tasks, or acts of a process (e.g., a method claim) actually recite an order, the steps, tasks, or acts should not be construed to require one.

First, as illustrated in FIG. 6, a display element 310 may be formed on a substrate 100. A pixel circuit layer 200 may be arranged on the substrate 100. For example, before the display element 310 is formed on the substrate 100, a semiconductor layer Act may be formed on the substrate 100, a gate insulating layer IIL1 may be formed on the semiconductor layer Act, and a gate electrode GE may be formed on the gate insulating layer IIL1. A first interlayer insulating layer IIL2 may be formed on the gate electrode GE, and a source electrode SE and a drain electrode DE may be formed on the first interlayer insulating layer IIL2. A second interlayer insulating layer IIL3 may be formed on the source electrode SE and the drain electrode DE, and an organic insulating layer OIL may be formed on the second interlayer insulating layer IIL3. A pixel electrode 311 may be formed on the organic insulating layer OIL, and a pixel defining layer 320 having a pixel opening may be formed to cover the edge of the pixel electrode 311. An intermediate layer 312 may be formed on the pixel electrode 311 and the pixel defining layer 320, and an opposite electrode 313 may be formed on the intermediate layer 312 and the pixel defining layer 320. For example, the display element 310 may be formed on the substrate 100, and the display element 310 may include the pixel electrode 311, the intermediate layer 312, and the opposite electrode 313.

In other words, before the display element 310 is formed on the substrate 100, the pixel circuit layer 200 described above with reference to FIG. 3 may be formed on the substrate 100. For example, the semiconductor layer Act, the gate electrode GE, the source electrode SE, and the drain electrode DE, which are included in a thin-film transistor TFT, may be formed on the substrate 100. The gate insulating layer IIL1 may be formed between the semiconductor layer Act and the gate electrode GE, and the first interlayer insulating layer IIL2 may be formed between the gate electrode GE, the source electrode SE, and the drain electrode DE. The second interlayer insulating layer IIL3 may be formed on the thin-film transistor TFT, and the organic insulating layer OIL may be formed on the second interlayer insulating layer IIL3. The display element 310 may be formed on the organic insulating layer OIL. Because the formation of the pixel circuit layer 200, the pixel defining layer 320, and the display element 310 is common in manufacturing the display apparatus, detailed descriptions thereof are omitted (not repeated).

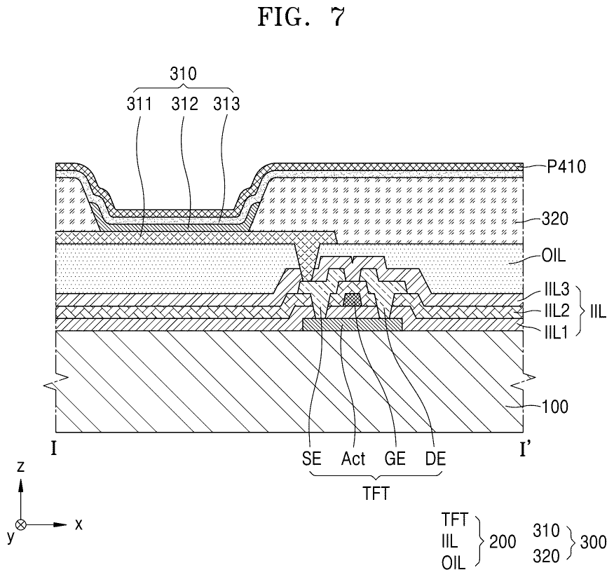

As illustrated in FIG. 7, a first preliminary layer P410 may be formed to cover the display element 310. For example, the first preliminary layer P410 may be formed by applying a material for forming (or providing) a first layer, including polysilazane, to cover the display element 310. For example, the material for forming (or providing) the first layer may be discharged onto the display element 310 by inkjet printing. The material for forming (or providing) the first layer may include polysilazane. The material for forming (or providing) the first layer may be a solution prepared by mixing polysilazane with a first solvent. The first solvent may be removed by drying the material for forming (or providing) the first layer discharged onto the display element 310, and thus, the first preliminary layer P410 may be formed to cover the display element 310.

The polysilazane may be PHPS. The first solvent may include at least one of xylene, toluene, ethylbenzene, diethylbenzene, mesitylene, propylbenzene, cyclohexylbenzene, dimethoxybenzene, anisole, ethoxytoluene, phenoxytoluene, isopropyl biphenyl, dimethylanisole, propylanisole, 1-ethylnaphthalene, 2-ethylnaphthalene, 2-ethylbiphenyl, or octylbenzene. However, the disclosure is not limited thereto. In some embodiments, the material for forming (or providing) the first layer may further include a photocuring agent. The photocuring agent may be included as long as the photocuring agent is utilized to photocure polysilazane, and is not particularly limited. For example, the material for forming (or providing) the first layer may be a solution in which the polysilazane and the photocuring agent are dissolved in the first solvent. In another embodiment, the first preliminary layer P410 may be formed by slit coating or spin coating.

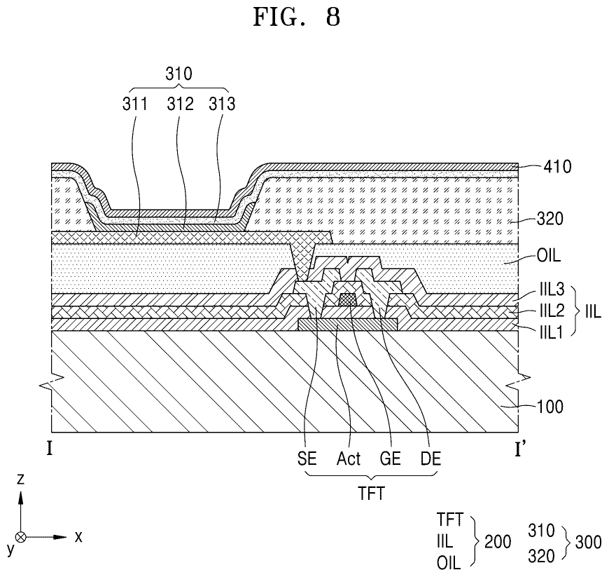

As illustrated in FIG. 8, the first layer 410 may be formed by emitting ultraviolet light to the first preliminary layer P410. For example, the first layer 410 may be the photocured first preliminary layer P410. For example, ultraviolet light having a light intensity of about 1,000 mJ/cm² to about 3,000 mJ/cm² may be emitted to the first preliminary layer P410. For example, ultraviolet light having a light intensity of about 2,000 mJ/cm² may be emitted to the first preliminary layer P410. Ultraviolet light having a wavelength of about 300 nm to about 400 nm may be utilized for the photocuring. A light-emitting diode (LED) or a metal halide may be utilized as an ultraviolet source. As ultraviolet light is emitted to the first preliminary layer P410, the first preliminary layer P410 may be photocured. In the case of forming (or providing) the first layer 410 by curing polysilazane, a process time and a manufacturing cost may be reduced, compared to forming (or providing) an inorganic insulating layer including silicon oxide (SiOₓ), silicon nitride (SiNₓ), and/or silicon oxynitride (SiOₓN_{y}) by utilizing chemical vapor deposition CVD, and/or the like.

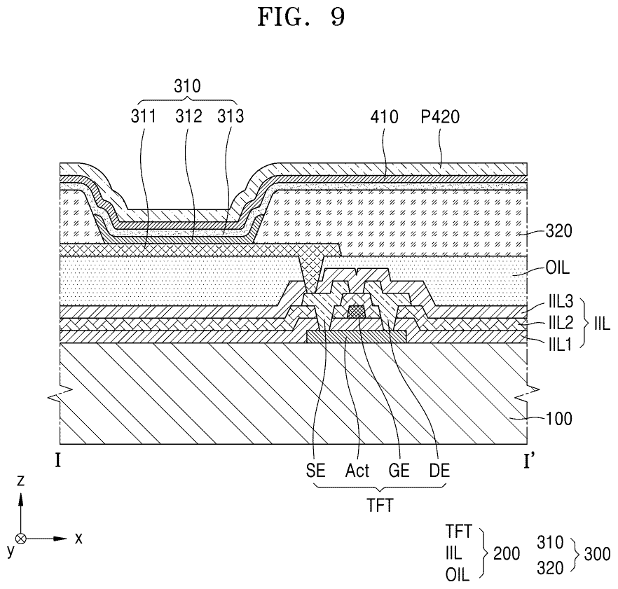

As illustrated in FIG. 9, a second preliminary layer P420 may be formed on the first layer 410. For example, the second preliminary layer P420 may be formed by applying a material for forming (or providing) a second layer, including a silicon-based vinyl monomer, onto the first layer 410. For example, the material for forming (or providing) the second layer may be discharged onto the first layer 410 by inkjet printing. The material for forming (or providing) the second layer may include a silicon-based vinyl monomer. The material for forming (or providing) the second layer may be a solution prepared by mixing a silicon-based vinyl monomer with a second solvent. The second solvent may be removed by drying the material for forming (or providing) the second layer discharged onto the first layer 410, and thus, the second preliminary layer P420 may be formed on the first layer 410.

The silicon-based vinyl monomer may include at least one of vinyltrimethylsilane, vinyltriethylsilane, vinyltrimethoxysilane, vinyltriethoxysilane, vinyltris(2-methoxyethoxy)silane, vinyltrisisopropoxysilane, vinyltris(tertbutylperoxy)silane, vinyldimethylethoxysilane, vinylmethyldimethoxysilane, vinylmethyldiethoxysilane, 1,1,3,3-tetramethyl-1,3-divinyldisiloxane, 2,4,6,8-tetramethyl-2,4,6,8-tetravinyl-cyclotetrasiloxane, or 1,3,5-trivinyl-1,3,5-trimethylcyclotrisiloxane. In some embodiments, the silicon-based vinyl monomer may be vinyltrimethylsilane. However, the disclosure is not limited thereto.

The second solvent may include at least one of xylene, toluene, ethylbenzene, diethylbenzene, mesitylene, propylbenzene, cyclohexylbenzene, dimethoxybenzene, anisole, ethoxytoluene, phenoxytoluene, isopropyl biphenyl, dimethylanisole, propylanisole, 2-ethylnaphthalene, 2-ethylnaphthalene, 2-ethylbiphenyl, or octylbenzene. However, the disclosure is not limited thereto. In some embodiments, the material for forming (or providing) the second layer may further include a photocuring agent. The photocuring agent may be included as long as the photocuring agent is utilized to photocure the silicon-based vinyl monomer, and is not particularly limited. For example, the material for forming (or providing) the second layer may be a solution in which the silicon-based vinyl monomer and the photocuring agent are dissolved in the second solvent. In another embodiment, the second preliminary layer P420 may be formed by slit coating or spin coating.

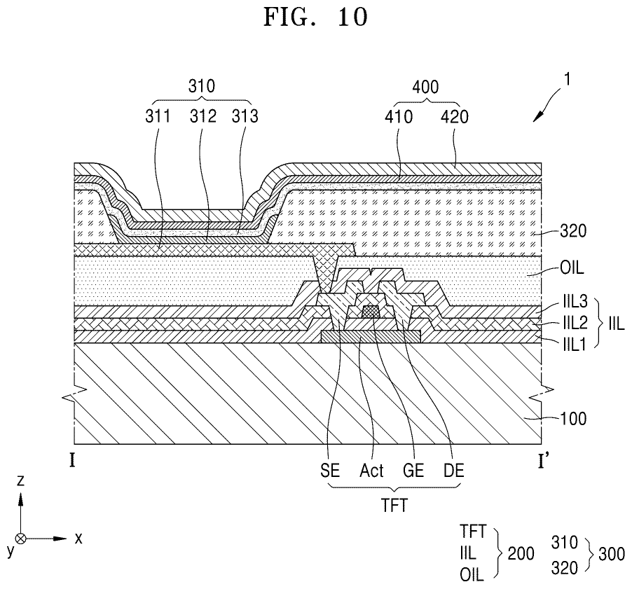

As illustrated in FIG. 10, the second layer 420 may be formed by emitting ultraviolet light to the second preliminary layer P420. For example, the second layer 420 may be the photocured second preliminary layer P420. For example, ultraviolet light having a light intensity of about 1,000 mJ/cm² to about 3,000 mJ/cm² may be emitted to the second preliminary layer P420. For example, ultraviolet light having a light intensity of about 2,000 mJ/cm² may be emitted to the second preliminary layer P420. Ultraviolet light having a wavelength of about 300 nm to about 400 nm may be utilized for photocuring. An LED or a metal halide may be utilized as an ultraviolet source. As ultraviolet light is emitted to the second preliminary layer P420, the second preliminary layer P420 may be photocured.

The encapsulation layer 400 including the first layer 410 and the second layer 420 may be thin. For example, the thickness of the encapsulation layer 400, which is the sum of the thickness of the first layer 410 and the thickness of the second layer 420, may be about 0.3 μm to about 1.0 μm. Because the thickness of the encapsulation layer 400 including the first layer 410 and the second layer 420 has been described above with reference to FIG. 3, redundant description thereof are omitted (not repeated).

In some embodiments, a portion of the silicon-based vinyl monomer utilized to form (or provide) the second layer 420 may undergo a reaction with the polysilazane of the first layer 410 during the formation of the second layer 420 as shown in Reaction Scheme 1 above. For example, a portion of the polysilazane of the first layer 410 may form (or provide) a covalent bond with the silicon-based vinyl monomer. Silicon (Si) of a portion of the polysilazane of the first layer 410 and carbon (C) of the silicon-based vinyl monomer may form a covalent bond. For example, the polysilazane of the first layer 410 may form a Si—C bond with the silicon-based vinyl monomer. For example, when the material for forming (or providing) the second layer is discharged onto the first layer 410 by inkjet printing, a portion of the material for forming (or providing) the second layer may be in contact with the surface of the first layer 410. In one or more embodiments, another portion of the material for forming (or providing) the second layer may also penetrate into the first layer 410. The silicon-based vinyl monomer, which is included in a portion of the material for forming (or providing) the second layer or another portion of the material for forming (or providing) the second layer, may undergo a reaction with the polysilazane of the first layer 410 due to a certain amount of heat generated when ultraviolet light is emitted, as shown in Reaction Formula 1 above. Accordingly, the film quality of the first layer 410 may become denser. For example, the density of the first layer 410 may further increase. Accordingly, fine cracks present on the surface of the first layer 410 may be removed.

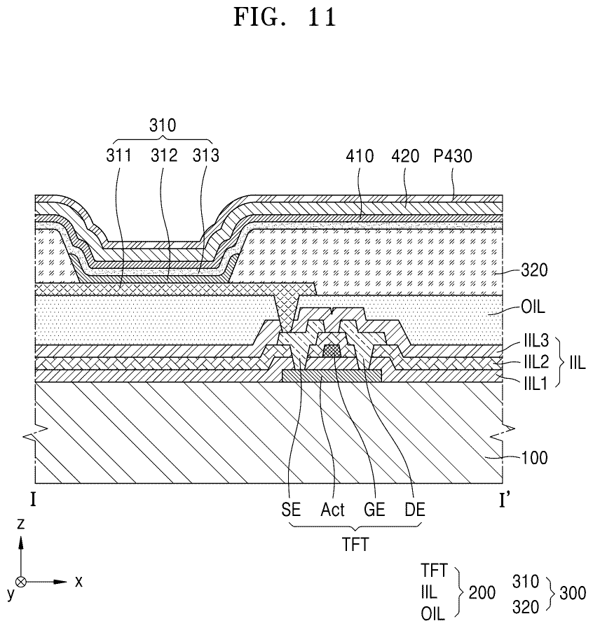

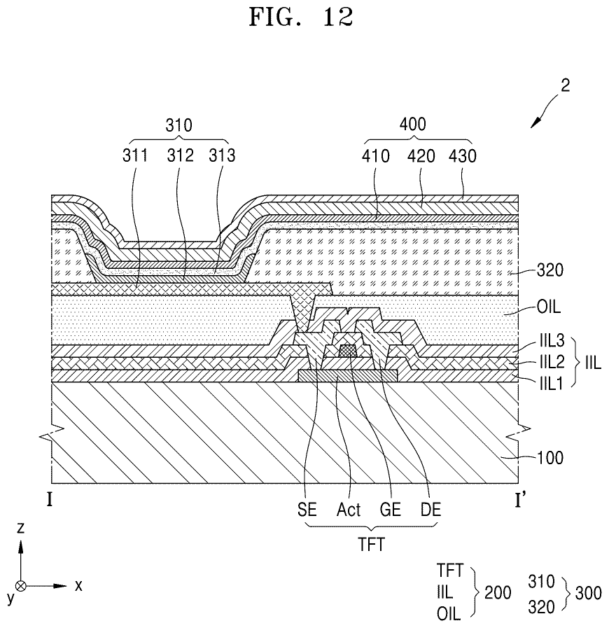

FIGS. 11 and 12 are cross-sectional views schematically illustrating a process of manufacturing a portion of the display apparatus 2 of FIG. 4. For example, FIGS. 11 and 12 are cross-sectional views schematically illustrating part of a process of manufacturing the encapsulation layer 400 of the display apparatus 2 of FIG. 4. In FIGS. 11 and 12, for convenience of explanation, part of the process of manufacturing the encapsulation layer 400 is described based on a cross-section of the display apparatus 2 of FIG. 4 taken along the line I-I′ of FIG. 1. Because the process of manufacturing a portion of the display apparatus 2 according to the present embodiment is similar to the process of manufacturing a portion of the display apparatus 1 described above with reference to FIGS. 6-10, differences from the process of manufacturing the display apparatus 1 described above with reference to

FIGS. 6-10 are mainly described. In FIGS. 11 and 12, because the same reference numerals as those in FIGS. 4 and 6-10 denote the same members, redundant descriptions thereof are omitted (not repeated).

In the case of manufacturing a portion of the display apparatus 1 described above with reference to FIGS. 6-10, the display element 310 may be formed on the substrate 100, and the first preliminary layer P410 may be formed to cover the display element 310. The first layer 410 may be formed by emitting ultraviolet light to the first preliminary layer P410. The second preliminary layer P420 may be formed on the first layer 410. The second layer 420 may be formed by emitting ultraviolet light to the second preliminary layer P420. In manufacturing a portion of the display apparatus 2, the display element 310 may be formed on the substrate 100, and the first preliminary layer P410 may be formed to cover the display element 310. The first layer 410 may be formed by emitting ultraviolet light to the first preliminary layer P410. The second preliminary layer P420 may be formed on the first layer 410. The second layer 420 may be formed by emitting ultraviolet light to the second preliminary layer P420.

After the second layer 420 is formed, the third preliminary layer P430 may be formed to cover the second layer 420, as illustrated in FIG. 11. For example, the third preliminary layer P430 may be formed by applying a material for forming (or providing) a third layer, including polysilazane, to cover the second layer 420. For example, the material for forming (or providing) the third layer may be discharged onto the second layer 420 by inkjet printing. The material for forming (or providing) the third layer may include polysilazane. The material for forming (or providing) the third layer may be a solution prepared by mixing polysilazane with a third solvent. The third solvent may be removed by drying the material for forming (or providing) the third layer discharged onto the second layer 420, and thus, the third preliminary layer P430 may be formed on the second layer 420.

The polysilazane may be PHPS. The third solvent may include at least one of xylene, toluene, ethylbenzene, diethylbenzene, mesitylene, propylbenzene, cyclohexylbenzene, dimethoxybenzene, anisole, ethoxytoluene, phenoxytoluene, isopropyl biphenyl, dimethylanisole, propylanisole, 3-ethylnaphthalene, 2-ethylnaphthalene, 2-ethylbiphenyl, or octylbenzene. However, the disclosure is not limited thereto. In some embodiments, the material for forming (or providing) the third layer may further include a photocuring agent. The photocuring agent may be included as long as the photocuring agent is utilized to photocure polysilazane, and is not particularly limited. For example, the material for forming (or providing) the third layer may be a solution in which the polysilazane and the photocuring agent are dissolved in the third solvent. In another embodiment, the third preliminary layer P430 may be formed by slit coating or spin coating.

As illustrated in FIG. 12, the third layer 430 may be formed by emitting ultraviolet light to the third preliminary layer P430. For example, the third layer 430 may be the photocured third preliminary layer P430. For example, ultraviolet light having a light intensity of about 1,000 mJ/cm² to about 3,000 mJ/cm² may be emitted to the third preliminary layer P430. For example, ultraviolet light having a light intensity of about 2,000 mJ/cm² may be emitted to the third preliminary layer P430. Ultraviolet light having a wavelength of about 300 nm to about 400 nm may be utilized for photocuring. An LED or a metal halide may be utilized as an ultraviolet source. As ultraviolet light is emitted to the third preliminary layer P430, the third preliminary layer P430 may be photocured. In the case of forming (or providing) the third layer 430 by curing polysilazane, a process time and a manufacturing cost may be reduced, compared to forming (or providing) an inorganic insulating layer including silicon oxide (SiOₓ), silicon nitride (SiNₓ), and/or silicon oxynitride (SiOₓN_{y}) by utilizing CVD, and/or the like.

The encapsulation layer 400 including the first layer 410, the second layer 420, and the third layer 430 may be thin. Because the thickness of the encapsulation layer 400 including the first layer 410, the second layer 420, and the third layer 430 has been described above with reference to FIG. 4, redundant description thereof are omitted (not repeated).

According to one or more embodiments, an encapsulation layer that is thin and is capable of blocking external moisture and/or oxygen, a display apparatus including the encapsulation layer, and a method of manufacturing the display apparatus may be implemented. The scope of the disclosure is not limited by such an aspect.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus, the display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. An encapsulation layer comprising:
a first layer comprising polysilazane; and
a second layer on the first layer and comprising a cured product of a silicon-based vinyl monomer.

2. The encapsulation layer of claim 1, wherein the polysilazane comprises perhydropolysilazane (PHPS).

3. The encapsulation layer of claim 1, wherein the silicon-based vinyl monomer comprises at least one of vinyltrimethylsilane, vinyltriethylsilane, vinyltrimethoxysilane, vinyltriethoxysilane, vinyltris(2-methoxyethoxy)silane, vinyltrisisopropoxysilane, vinyltris(tertbutylperoxy)silane, vinyldimethylethoxysilane, vinylmethyldimethoxysilane, vinylmethyldiethoxysilane, 1,1,3,3-tetramethyl-1,3-divinyldisiloxane, 2,4,6,8-tetramethyl-2,4,6,8-tetravinyl-cyclotetrasiloxane, or 1,3,5-trivinyl-1,3,5-trimethylcyclotrisiloxane.

4. The encapsulation layer of claim 1, wherein a portion of the polysilazane of the first layer forms a covalent bond with the silicon-based vinyl monomer.

5. The encapsulation layer of claim 1, wherein the second layer is in direct contact with the first layer.

6. The encapsulation layer of claim 1, wherein a thickness of the encapsulation layer is about 0.3 micrometers (μm) to about 1.0 μm.

7. The encapsulation layer of claim 1, further comprising a third layer on the second layer and comprising polysilazane.

8. A display apparatus comprising:
a substrate;
a display element on the substrate; and
an encapsulation layer covering the display element, the encapsulation layer comprising:
a first layer comprising polysilazane, and
a second layer on the first layer and comprising a cured product of a silicon-based vinyl monomer.

9. The display apparatus of claim 8, wherein the polysilazane comprises perhydropolysilazane (PHPS).

10. The display apparatus of claim 8, wherein the silicon-based vinyl monomer comprises at least one of vinyltrimethylsilane, vinyltriethylsilane, vinyltrimethoxysilane, vinyltriethoxysilane, vinyltris(2-methoxyethoxy)silane, vinyltrisisopropoxysilane, vinyltris(tertbutylperoxy)silane, vinyldimethylethoxysilane, vinylmethyldimethoxysilane, vinylmethyldiethoxysilane, 1,1,3,3-tetramethyl-1,3-divinyldisiloxane, 2,4,6,8-tetramethyl-2,4,6,8-tetravinyl-cyclotetrasiloxane, or 1,3,5-trivinyl-1,3,5-trimethylcyclotrisiloxane.

11. The display apparatus of claim 8, wherein a portion of the polysilazane of the first layer forms a covalent bond with the silicon-based vinyl monomer.

12. The display apparatus of claim 8, wherein the second layer is in direct contact with the first layer.

13. The display apparatus of claim 8, wherein a thickness of the encapsulation layer is about 0.3 micrometers (μm) to about 1.0 μm.

14. The display apparatus of claim 8, wherein the encapsulation layer further comprises a third layer on the second layer, the third layer comprising at least one of polysilazane, silicon nitride, silicon oxide, or silicon oxynitride.

15. A method of manufacturing a display apparatus, the method comprising:
forming a display element on a substrate;
forming a first preliminary layer by applying a material comprising polysilazane to cover the display element;
forming a first layer by emitting ultraviolet light to the first preliminary layer;
forming a second preliminary layer by applying a material comprising a silicon-based vinyl monomer on the first layer; and
forming a second layer by emitting ultraviolet light to the second preliminary layer.

16. The method of claim 15, wherein the polysilazane comprises perhydropolysilazane (PHPS).

17. The method of claim 15, wherein the silicon-based vinyl monomer comprises at least one of vinyltrimethylsilane, vinyltriethylsilane, vinyltrimethoxysilane, vinyltriethoxysilane, vinyltris(2-methoxyethoxy)silane, vinyltrisisopropoxysilane, vinyltris(tertbutylperoxy)silane, vinyldimethylethoxysilane, vinylmethyldimethoxysilane, vinylmethyldiethoxysilane, 1,1,3,3-tetramethyl-1,3-divinyldisiloxane, 2,4,6,8-tetramethyl-2,4,6,8-tetravinyl-cyclotetrasiloxane, or 1,3,5-trivinyl-1,3,5-trimethylcyclotrisiloxane.

18. The method of claim 15, wherein, in the forming of the second layer, a portion of the polysilazane of the first layer forms a covalent bond with the silicon-based vinyl monomer.

19. The method of claim 15, wherein a sum of a thickness of the first layer and a thickness of the second layer is about 0.3 micrometers (μm) to about 1.0 μm.

20. The method of claim 15, further comprising:
forming a third preliminary layer by applying a material comprising polysilazane to cover the second layer; and
forming a third layer by emitting ultraviolet light to the third preliminary layer.
